(19) United States
(12) Patent Application Publication
(10) Pub. No.: US 2025/0178012 A1
(43) Pub. Date: Jun. 5, 2025

(54) PORTABLE COATING DEVICE

(71) Applicant: Metal Industries Research & Development Centre, Kaohsiung (TW)

(72) Inventors: Kuo-Yu Chien, Chiayi County (TW); Zong-Hsin Liu, Kaohsiung City (TW); Hsien-Ju Wu, Kaohsiung City (TW); Hsiang-Pin Wang, Kaohsiung City (TW); Po-Chi Hu, Kaohsiung City (TW); Chih-Hsuan Huang, Kaohsiung City (TW); Jia Yan Lin, Kaohsiung City (TW); Chun-Mu Wu, Kaohsiung City (TW); Yi Yan Li, Kaohsiung City (TW); Zong Lun Wu, Taichung City (TW); Cheng-Tang Pan, Kaohsiung City (TW); Ming-Cheng Lin, Kaohsiung City (TW)

(73) Assignee: Metal Industries Research & Development Centre, Kaohsiung (TW)

(21) Appl. No.: 18/523,909

(22) Filed: Nov. 30, 2023

(51) Int. Cl. B05B 12/28; B05B 9/00; B05B 9/043; B05B 12/00; B05B 12/02

(52) U.S. Cl. CPC B05B 12/28; B05B 9/043; B05B 12/02; B05B 9/007; B05B 12/002

(57) ABSTRACT

A portable coating device for applying a coating solution onto a solar panel includes a supply module for supplying the coating solution, a base, a spraying module disposed on the base, a transmission module disposed at two opposite ends of the base, an arc bracket, and an applicator. The base spans the solar panel and moves thereon through the support of the transmission module. The arc bracket is disposed at the bottom of the base and has a plurality of seepage openings, and an inner surface of the arc bracket faces the spraying module. The applicator includes a porous material that deforms under pressure. The applicator is assembled to the base and supported by the arc bracket.

### TECHNICAL FIELD

The disclosure relates to a coating device, and particularly relates to a portable coating device.

### BACKGROUND

Solar energy is a valuable asset in nature. With the development of clean energy, the technology for converting solar energy into electrical energy through solar panels has continuously evolved in recent years.

A solar panel usually has a protective top layer covered with glass or plastic to protect the solar cells underneath. From the aspect of improving solar cell efficiency, performance-enhancing coatings, such as anti-reflective coatings (or films) on the glass or top layer, are beneficial to transmission of light. Therefore, providing additional anti-reflective coatings or films on solar panels becomes one of the manufacturing processes of solar panels.

The existing processes for forming such coatings or films mostly involve blade coating, spin coating or vacuum deposition. However, for solar panels with larger areas, the aforementioned approaches not only make it difficult to uniformize the coatings or films, but also cause a waste of the coating or film materials. Especially for solar panels that have been manufactured or are already in use, repeatedly removing solar panels from the working environment and then sending them to the coating factory for cleaning and application may significantly increase the production cost and easily cause damage. Therefore, how to provide effective and simple coating (or film forming) equipment is an issue that needs to be addressed in this field.

### SUMMARY

The disclosure provides a portable coating device which facilitates application of a coating solution onto a solar panel in an outdoor environment without being restricted by the field.

A portable coating device according to an embodiment of the disclosure is configured to apply a coating solution onto a solar panel. The portable coating device includes a supply module, a base, a spraying module, a transmission module, an arc bracket, and an applicator. The spraying module is disposed on the base and connected to the supply module. The transmission module is disposed at two opposite ends of the base so that the base spans the solar panel, and the base moves on the solar panel through support of the transmission module. The arc bracket is disposed at a bottom of the base and has multiple seepage openings. The applicator includes a porous material that deforms under pressure. The applicator is assembled to the base and supported by a surface of the arc bracket. The supply module transmits the coating solution to the spraying module, and the spraying module sprays the coating solution onto the arc bracket so that the coating solution seeps to the applicator through the seepage openings to be adsorbed by the applicator. As the base moves on the solar panel through the transmission module, the applicator abuts the solar panel to apply the coating solution onto the solar panel.

In an embodiment of the disclosure, the spraying module includes a plurality of nozzles arranged along an extension direction of the base. Each of the nozzles is disposed through the base to face an inner surface of the arc bracket. The coating solution transmitted from the supply module is transmitted to the nozzles through a pipe, and the nozzles spray the coating solution onto the inner surface of the arc bracket.

In an embodiment of the disclosure, the transmission module includes a pair of transmission components and at least one motor, and the pair of transmission components are separately disposed at the two opposite ends of the base so that the spraying module is located between the pair of transmission components. Each of the transmission components includes a U-shaped bracket and at least one guide wheel. The U-shaped bracket is movably assembled to the base and spans the base. The at least one guide wheel is disposed at an end of the U-shaped bracket so that the U-shaped bracket is supported on the solar panel through the at least one guide wheel, and the motor is connected to and drives the at least one guide wheel.

In an embodiment of the disclosure, the at least one guide wheel moves on a frame of the solar panel so that the applicator moves on protective glass inside the frame.

In an embodiment of the disclosure, the portable coating device further includes at least one adjustment screw that movably locks the base and the U-shaped bracket to adjust a gap of the base and the applicator assembled thereon relative to the protective glass of the solar panel.

In an embodiment of the disclosure, the portable coating device further includes a spring that is disposed through the U-shaped bracket and abuts between the base and the U-shaped bracket. The spring constantly drives the U-shaped bracket away from the base.

In an embodiment of the disclosure, the portable coating device further includes a front drive wheel that is connected between the U-shaped brackets of the pair of transmission components and maintains a distance from the applicator. In response to the base moving on the solar panel and the applicator applying the coating solution onto the solar panel, the front drive wheel travels in front of the applicator.

In an embodiment of the disclosure, the applicator includes a sponge and a fabric. The sponge abuts an outer surface of the arc bracket, and the fabric tightly covers the sponge and is fixed to the base so that the sponge is located between the arc bracket and the fabric.

In an embodiment of the disclosure, the applicator further includes a reel and a clamping block. The clamping block is assembled to a first side of the base to clamp a side edge of the fabric, and the reel is disposed on a second side of the base to fix the other side edge of the fabric so that the fabric tightly abuts the sponge.

In an embodiment of the disclosure, the applicator further includes an adjustment block, a guide post, a spring, and an adjustment screw. The guide post is disposed on the base and passes through the adjustment block. The adjustment block is movable along the guide post to move away from or close to the base. The spring is disposed through the adjustment block and one end of the spring abuts the base. The adjustment screw is movably locked to the adjustment block and abuts the other end of the spring. The adjustment screw is adapted to rotate under force to adjust a position of the adjustment block relative to the base, and the reel is assembled to the adjustment block.

In an embodiment of the disclosure, the portable coating device further includes a support bar that is pivotally connected to the base to be held by a user.

Based on the above, the portable coating device is an adsorption carrier in which the applicator including a flexible (deformable) porous material is disposed on the arc bracket so that the arc bracket supports the applicator and deforms the applicator to be consistent with the contour of the arc bracket. Furthermore, the spraying module is disposed on the base and the spraying nozzles thereof pass through the base to faces the arc bracket, and the arc bracket has multiple seepage openings. Therefore, the coating solution provided from the supply module to the spraying module may be sprayed on the arc bracket by the spraying module, and then flow out of the arc bracket through the seepage openings and flow into the applicator for the applicator to adsorb the coating solution.

Accordingly, when the base moves on the frame of the solar panel through the transmission module, the base spanning the solar panel may move over the solar panel. This also means that the applicator located at the bottom of the base moves on the solar panel together with the base. In this way, the applicator adsorbing the coating solution abuts the solar panel during the movement, and applies the coating solution onto the solar panel to protect the solar panel and increase the light reception.

It can be seen from the above that the portable coating device of the disclosure first uses the material characteristics of the applicator to temporarily store the coating solution, and the applicator is supported and deformed by the arc bracket to have an arc-shaped contour, which allows the applicator to contact the solar panel at a fixed position and by a fixed area and apply the coating solution onto the solar panel when moving on and abutting the solar panel. Therefore, the coating solution may be effectively utilized without being wasted.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic view of the structure and usage of the portable coating device according to an embodiment of the disclosure.

FIG. 1B is a diagram of the electrical connection between some components in FIG. 1A.

FIG. 2A is an exploded view of some components in FIG. 1A.

FIG. 2B and FIG. 2C respectively illustrate the portable coating device in FIG. 1A from different perspectives.

FIG. 3 is an exploded view of some components in FIG. 1A.

FIG. 4 is a partial cross-sectional view of the portable coating device in FIG. 1A.

FIG. 5 is an exploded view of some components in FIG. 1A.

FIG. 6 and FIG. 7 are respectively partial cross-sectional views of the portable coating device in FIG. 1A at different parts.

FIG. 8 is a schematic view of the portable coating device according to another embodiment of the disclosure.

### DETAILED DESCRIPTION OF DISCLOSED EMBODIMENTS

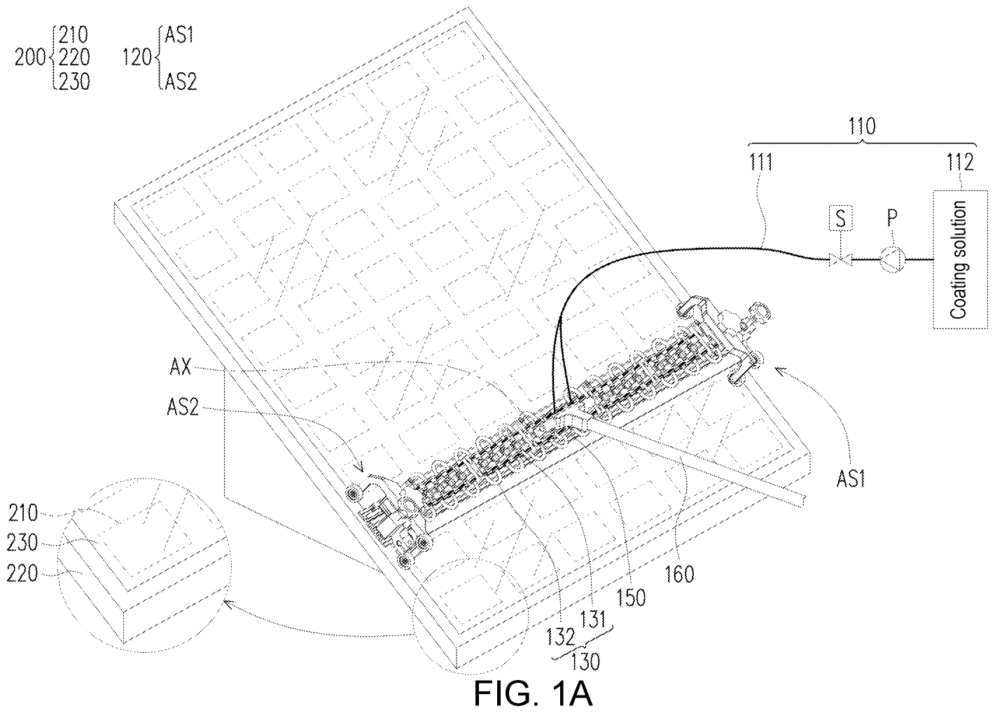

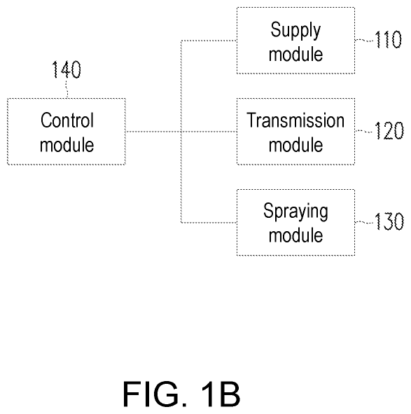

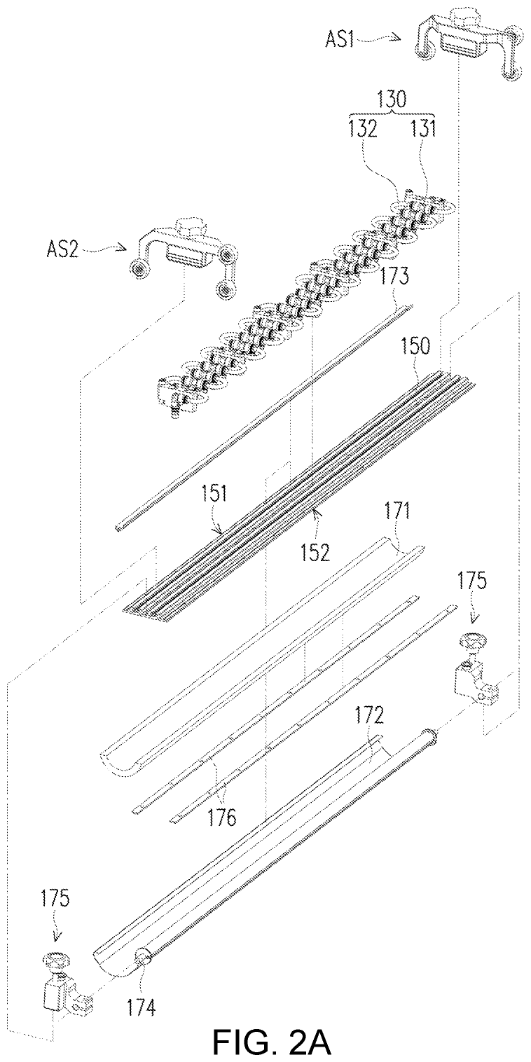

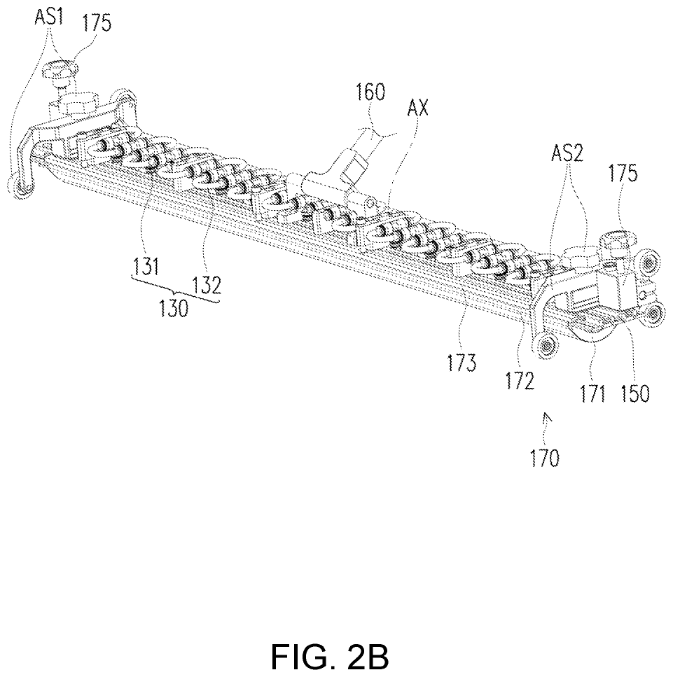

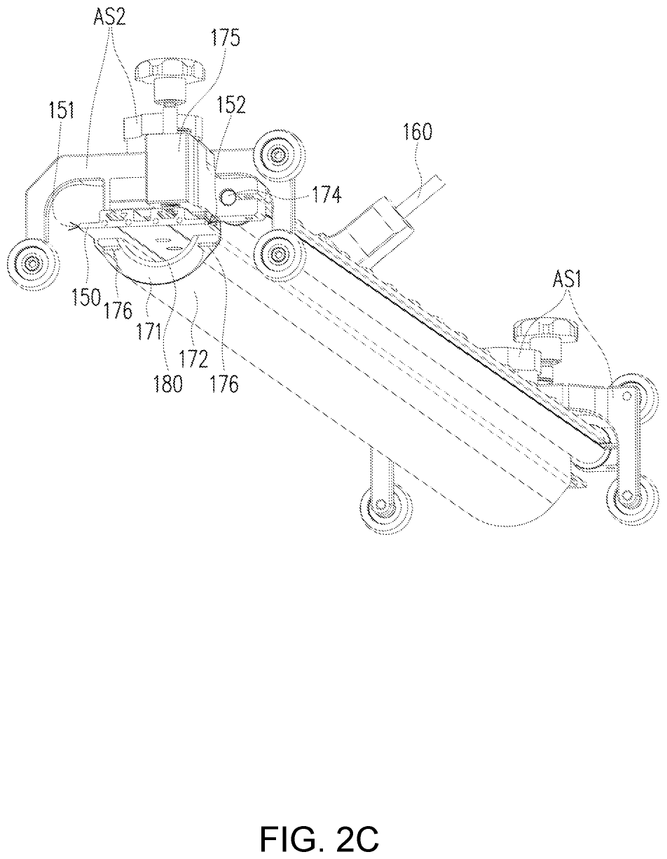

FIG. 1A is a schematic view of the structure and usage of the portable coating device according to an embodiment of the disclosure. FIG. 1B is a diagram of the electrical connection between some components in FIG. 1A. FIG. 2A is an exploded view of some components in FIG. 1A. FIG. 2B and FIG. 2C respectively illustrate the portable coating device in FIG. 1A from different perspectives. First, referring to FIG. 1A, in this embodiment, the portable coating device 100 is configured to apply a coating solution onto a solar panel 200, which allows the user to easily operate the portable coating device 100 in an outdoor environment without the need to consider the disassembly and assembly of the solar panel 200.

Next, referring to FIG. 1A, FIG. 2B, and FIG. 2C, the portable coating device 100 includes a supply module 110, a transmission module 120, a spraying module 130, a base 150, a support bar 160, an applicator 170, and an arc bracket 180. As shown in FIG. 1A, the support bar 160 is pivoted on the base 150 along an axis AX, allowing the user to hold the support bar 160 and put the base 150 and the related modules thereon against the solar panel 200. Furthermore, the supply module 110 includes a pipeline 111, a container 112, a pump P, and a solenoid valve S. The container 112 is configured to contain the coating solution. The pipeline 111 is connected between the container 112 and the spraying module 130. The user is allowed to control the amount of flow and the flow rate of the coating solution through the pump P and the solenoid valve S. For example, the pump P is a quantitative pump, which enables the coating solution to be continuously or intermittently transmitted to the spraying module 130 in a quantitative manner.

Referring to FIG. 1B, the portable coating device 100 of this embodiment further includes a control module 140, which is electrically connected to the supply module 110, the transmission module 120, and the spraying module 130. Therefore, for the supply module 110, the user may electrically connect and operate the pump P and the solenoid valve S through the control module 140, that is, the relevant electronic unit (for example, MCU (MicroController Unit)) disposed at the base 150 or the support bar 160, to achieve the aforementioned specific effect of transmitting the coating solution to the spraying module 130. The control module 140 may be manually controlled by the user or automatically controlled by a program.

In addition, the coating solution of this embodiment includes relevant functional coatings for the solar panel 200, such as anti-reflective (light) coatings, light wavelength-shifting coatings, coatings that filter ultraviolet or infrared rays, antifouling coatings, self-cleaning coatings, or thermal insulation coatings.

Referring to FIG. 2A, in this embodiment, the portable coating device 100 uses the base 150 as the main carrier structure, and the transmission module 120, the spraying module 130, the support bar 160, the applicator 170, and the arc bracket 180 are respectively assembled to the base 150. The modules or components will be described separately below.

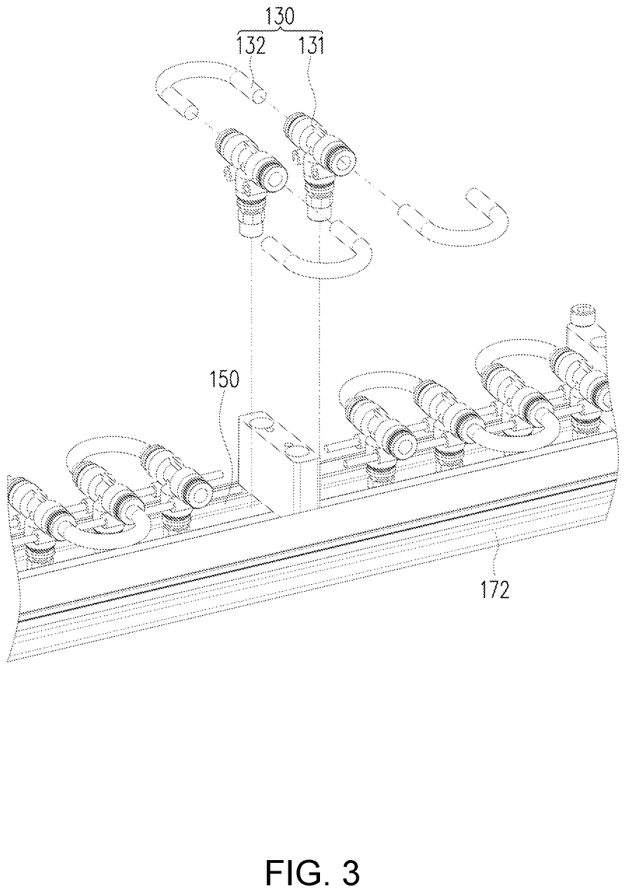

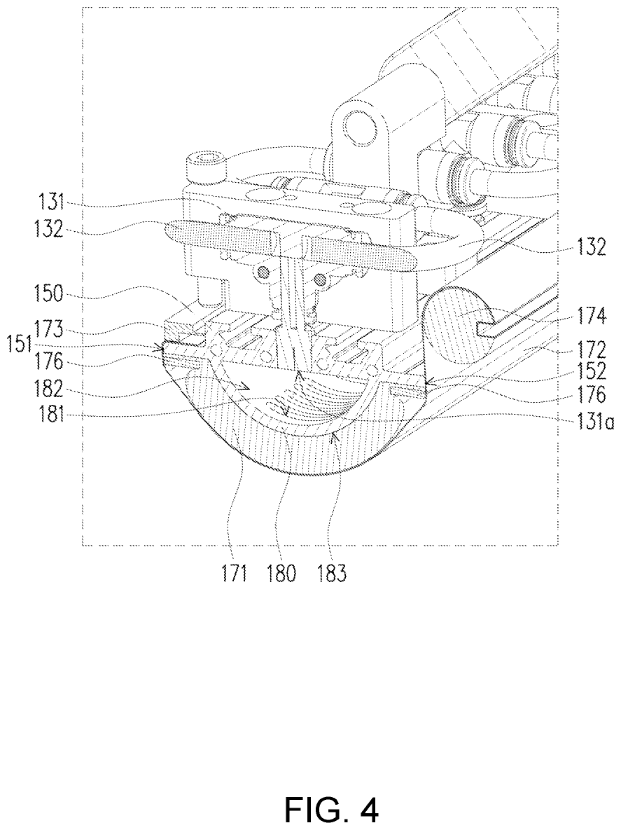

FIG. 3 is an exploded view of some components in FIG. 1A. FIG. 4 is a partial cross-sectional view of the portable coating device in FIG. 1A. Referring to FIG. 1A, FIG. 3, and FIG. 4, in this embodiment, the spraying module 130 includes a plurality of pipes 132 and a plurality of nozzles 131 that are staggered and connected in series. The nozzles 131 are, for example, atomizing nozzles, and are arranged along an extension direction of the base 150. The arc bracket 180 is assembled at the bottom of the base 150. Each nozzle 131 is disposed through the base 150 and faces an inner surface 182 of the arc bracket 180 with an outlet 131a, thereby transmitting the coating solution transmitted from the supply module 110 to the nozzle 131 through the pipe 132. The control module 140 is electrically connected to and drives the nozzle 131 to spray the coating solution onto the inner surface 182 of the arc bracket 180. The arc bracket 180 also has a plurality of seepage openings 181 which communicate the inner surface 182 with an outer surface 183 of the arc bracket 180. The outlet 131a of the nozzle 131 corresponds to the seepage opening 181, which facilitates the coating solution to be sprayed from the nozzle 131 to the inner surface 182 and then flow smoothly from the inner surface 182 to the outer surface 183.

Furthermore, the applicator 170 includes a porous material that may deform under pressure. The applicator 170 is assembled to the base 150 and supported by the arc bracket 180. Further, the applicator 170 includes a sponge 171 and a fabric 172. The sponge 171 abuts the outer surface 183 of the arc bracket 180, and the fabric 172 tightly covers the sponge 171 and is fixed to the base 150 so that the sponge 171 is located between the arc bracket 180 and the fabric 172. The aforementioned coating solution flowing out of the arc bracket 180 is sucked into the sponge 171 and temporarily stored. In this embodiment, the sponge 171 is soft and deformable, and the fabric 172 is a felt-like structure with micropores, such as suede, which is also a soft and deformable material. In order to prevent the applicator 170 from shaking arbitrarily and uncontrollably during application of the coating solution, in this embodiment, in addition to the arc bracket 180 serving as the main support structure, as shown in FIG. 2A and FIG. 4, the applicator 170 further includes a reel 174 and a clamping block 173. The clamping block 173 is assembled to a first side 151 of the base 150 to clamp a side edge of the fabric 172, and the reel 174 is disposed on a second side 152 of the base 150 to fix the other side edge of the fabric 172. In this way, the fabric 172 may be fixed on both opposite sides and be stretched to tightly abut the sponge 171.

Here, the applicator 170 is supported by the arc bracket 180 and clamped and stretched by the relevant components, which ensures the contact area when the applicator 170 contacts the protective glass 230 of the solar panel 200. For example, the applicator 170 and the protective glass 230 may be in linear contact with each other.

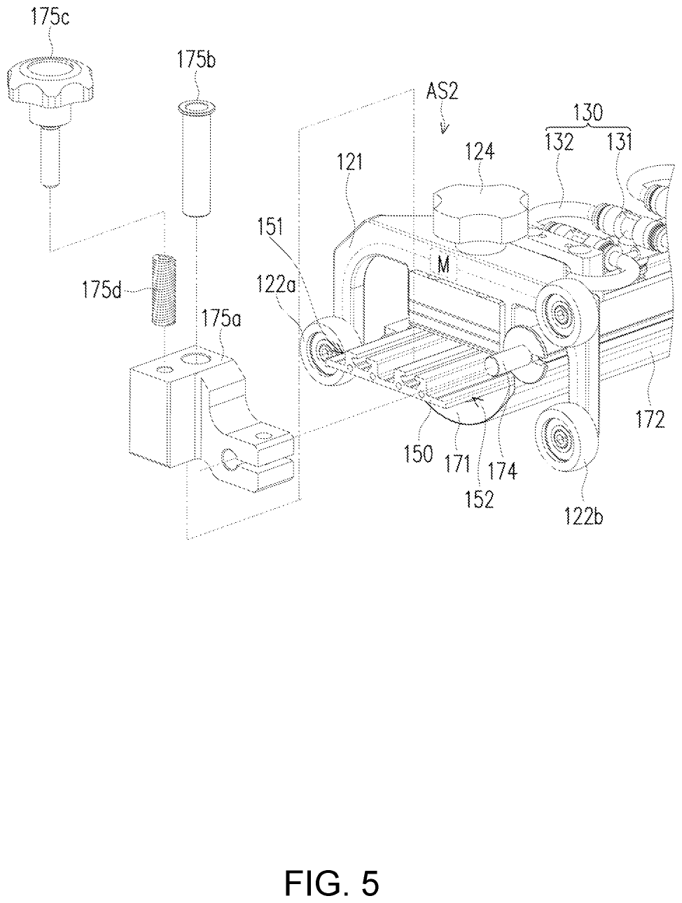

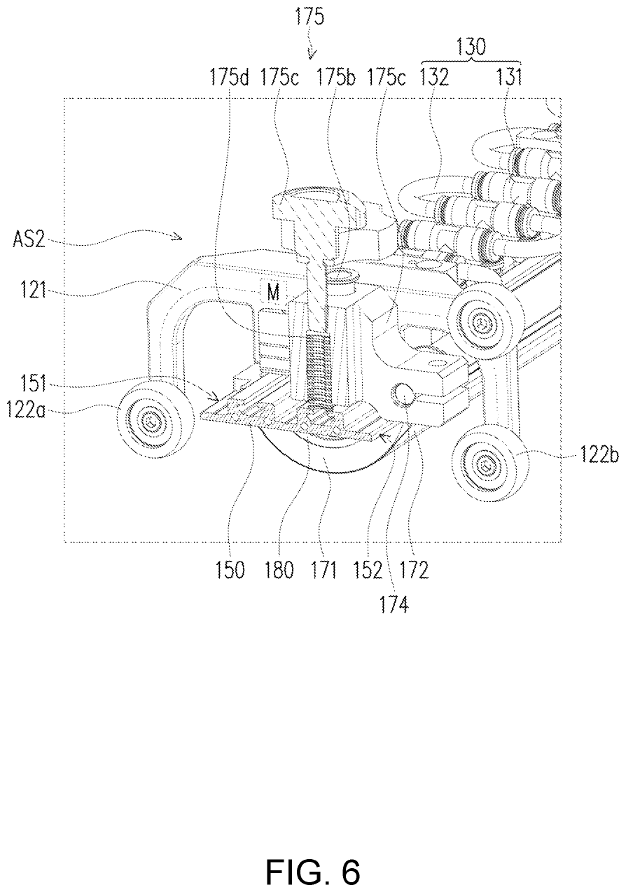

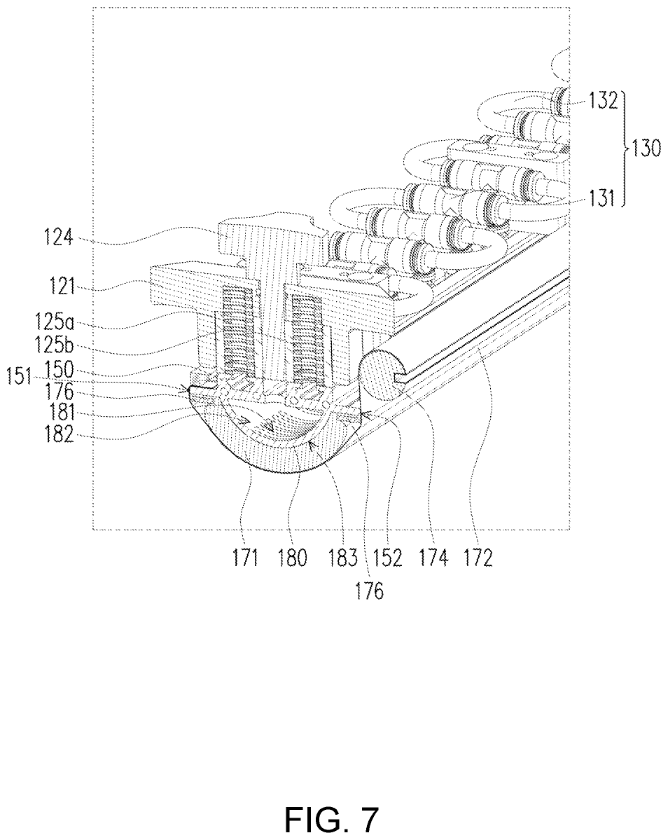

FIG. 5 is an exploded view of some components in FIG. 1A. FIG. 6 and FIG. 7 are respectively cross-sectional views of the portable coating device in FIG. 1A at different parts. Referring to FIG. 5 and FIG. 6 together with FIG. 2A, as shown in FIG. 2A, the applicator 170 further includes an adjustment mechanism 175 to further adjust and stretch the aforementioned fabric 172. Then, referring to FIG. 5 and FIG. 6, the adjustment mechanism 175 of the applicator 170 further includes an adjustment block 175a, a guide post 175b, a spring 175d, and an adjustment screw 175c. The guide post 175b is disposed on the base 150 and passes through the adjustment block 175a so that the adjustment block 175a is movable along the guide post 175b to move away from or close to the base 150. In addition, the spring 175d is disposed through the adjustment block 175a and one end of the spring 175d abuts the base 150. The adjustment screw 175c is movably locked to the adjustment block 175a and abuts the other end of the spring 175d. The reel 174 is assembled to the adjustment block 175a to be movable relative to the base 150. Accordingly, the user may drive the adjustment screw 175c to change the position of the adjustment block 175a relative to the base 150 and also change the position of the reel 174 relative to the base 150.

In other words, after one side edge of the fabric 172 is fixed to the first side 151 of the base 150 by the clamping block 173, the other side edge of the fabric 172 is clamped by the reel 174 to be wound by the reel 174. At the same time, the position of the reel 174 relative to the base 150 is adjusted by the aforementioned mechanism so as to smoothly tighten and attach the fabric 172 to the outer surface of the sponge 171 for coating.

Referring to FIG. 2A again, the transmission module 120 of this embodiment includes a pair of transmission components AS1 and AS2 and at least one motor M. The transmission components AS1 and AS2 are separately disposed at two opposite ends of the base 150 so that the spraying module 130 is located between the transmission components AS1 and AS2. Referring to FIG. 6 and FIG. 7 again, here, the transmission component AS2 is described as an example. The transmission component AS1 has the same configuration and will not be described again. In this embodiment, the transmission component AS2 includes a U-shaped bracket 121, a plurality of guide wheels 122a and 122b, and a motor M. The U-shaped bracket 121 is movably assembled to the base 150 and spans the base 150, and the guide wheels 122a and 122b are separately disposed at two opposite ends of the U-shaped bracket 121 so that the U-shaped bracket 121 is supported by the solar panel 200 through the guide wheels 122a and 122b (as shown in FIG. 1A). The motor M is connected to the guide wheels 122a and 122b to allow the control module 140 to drive the guide wheels 122a and 122b through the motor M. Here, the motor M drives the guide wheels 122a and 122b of the transmission component AS2, and the transmission component AS1 on the other side also uses another motor to drive a pair of guide wheels. However, the disclosure is not intended to limit how the motor is used for driving. In another embodiment not shown, a single motor may be used to drive all the guide wheels of the transmission components AS1 and AS2 at the same time.

Referring to FIG. 1A again, with the respective guide wheels 122a and 122b of the transmission components AS1 and AS2 supported on a frame 220 of the solar panel 200, the base 150 equipped with the transmission module 120 and the related modules assembled thereon span across a plurality of solar cell modules 210. When the portable coating device 100 applies coating (coating solution), the applicator 170 moves on and abuts the protective glass 230 of the solar panel 200. Accordingly, the driving of the control module 140 enables the motor M to drive the guide wheels 122a and 122b to travel on the solar panel 200 at a required speed, and with the spraying module 130 and the applicator 170, the coating solution may be evenly applied onto the protective glass 230.

More importantly, referring to FIG. 6 and FIG. 7 again, the transmission module 120 of this embodiment further includes an adjustment screw 124 and springs 125a and 125b. The adjustment screw 124 movably locks the base 150 and the U-shaped bracket 121, and the springs 125a and 125b pass through the U-shaped bracket 121 and abut between the base 150 and the U-shaped bracket 121. As shown in FIG. 7, since the springs 125a and 125b constantly exert force on the U-shaped bracket 121 to keep the U-shaped bracket 121 away from the base 150, the locking relationship between the adjustment screw 124, the base 150, and the U-shaped bracket 121 allows the relative distance between the U-shaped bracket 121 and the base 150 to be adjusted.

For example, when the adjustment screw 124 is loosened and moves upward relative to the U-shaped bracket 121, the elastic force of the springs 125a and 125b also drive the U-shaped bracket 121 to move upward, so that the U-shaped bracket 121 constantly abuts the adjustment screw 124. At this time, the U-shaped bracket 121 moves away from the base 150. On the contrary, when the adjustment screw 124 is tightened to resist the elastic force of the springs 125a and 125b, the U-shaped bracket 121 moves close to the base 150. Furthermore, as shown in FIG. 1A and FIG. 6, because the portable coating device 100 is supported on the solar panel 200 through the guide wheels 122a and 122b located at two opposite ends of the U-shaped bracket 121, changing the relative distance between the U-shaped bracket 121 and the base 150 is equivalent to changing the gap between the applicator 170 and the solar panel 200.

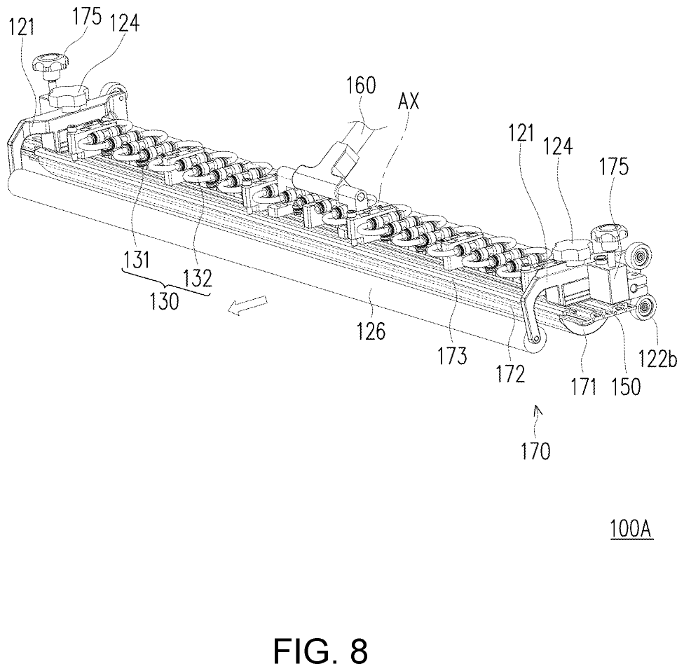

FIG. 8 is a schematic diagram of the portable coating device according to another embodiment of the disclosure. Referring to FIG. 8, the difference between the portable coating device 100A of this embodiment and the previous embodiment is that the transmission component of this embodiment includes a front drive wheel 126 in place of some of the guide wheels of the previous embodiment. As shown in FIG. 8, the front drive wheel 126 is connected between the pair of U-shaped brackets 121. The extension direction of the front drive wheel 126 (that is, wheel width direction) is consistent with the extension direction of the base 150 and maintains a distance from the applicator 170. When the base 150 moves on the solar panel 200 (as shown in FIG. 1A) and the applicator 170 applies the coating solution onto the solar panel 200, the front drive wheel 126 travels in front of the applicator 170. Since the front drive wheel 126 has a larger wheel width and is connected between the pair of U-shaped brackets 121, when the base 150 travels, the front drive wheel 126 serves as a guide for the base 150 to move stably in the traveling direction without deviation.

Based on the above, the user may adjust the gap between the base 150 and the applicator 170 assembled thereon relative to the protective glass 230 of the solar panel 200 according to the required film thickness (or coating thickness). In an implementation example, the user may accurately adjust the gap by using a gap piece (thickness gauge) as a basis for determining the gap. Besides, the close contact state between the fabric 172 and the solar panel 200 may be confirmed by using a pressure sensor. The control module 140 enables the supply module 110 to provide quantitative solution supply, enables the transmission module 120 to move at a constant speed, and with the adjustment screw 124 and the springs 125a and 125b, controls the gap between the applicator 170 and the surface of the solar panel 200, thereby achieving precise thickness control and uniformity for the coating. For example, in an implementation example, the control module 140 controls the transmission module 120 to move at a speed of 0.1 m/s to 0.32 m/s, and controls the supply module 110 to supply intermittently at 1 g/s to 10 g/s, thereby producing SiO₂ coating uniformly on the solar panel 200 with an area of 1.6*2m², and the thickness thereof is 72.66 nm to 228.36 nm.

To sum up, according to the above-described embodiments of the disclosure, the portable coating device is an adsorption carrier in which the applicator including a porous material that deforms under pressure is disposed on the arc bracket so that the arc bracket supports the applicator and deforms the applicator to be consistent with the contour of the arc bracket. Furthermore, the spraying module is disposed on the base and the spraying nozzles thereof pass through the base to faces the arc bracket, and the arc bracket has multiple seepage openings. Therefore, the coating solution provided from the supply module to the spraying module may be sprayed on the arc bracket by the spraying module, and then flow out of the arc bracket through the seepage openings and flow into the applicator for the applicator to adsorb the coating solution. The control module is electrically connected to the pump and solenoid valve of the supply module and the nozzles of the spraying module, thereby producing continuous (or intermittent) quantitative solution supply as required.

Furthermore, the base moves on the frame of the solar panel through the transmission module, which allows the base spanning the solar panel to move over the solar panel. This also means that the applicator located at the bottom of the base moves on the solar panel together with the base. In this way, the applicator adsorbing the coating solution abuts the solar panel during the movement, and applies the coating solution onto the solar panel to protect the solar panel and increase the light reception. The control module is electrically connected to the motor of the transmission module to achieve the effect of moving at a constant speed on the solar panel. In addition, the transmission module further includes the adjustment screw and the springs, whereby the relative distance between the U-shaped bracket and the base is changed so as to change the gap between the applicator and the solar panel. Therefore, with the aforementioned quantitative solution supply and constant speed movement, the thickness and uniformity of the coating may be ensured during the coating process.

It can be seen from the above that the portable coating device of the disclosure first uses the material characteristics of the applicator to temporarily store the coating solution, and the applicator is supported and deformed by the arc bracket to have an arc-shaped contour, which allows the applicator to contact the solar panel at a fixed position and by a fixed area and apply the coating solution onto the solar panel when moving on and abutting the solar panel. Therefore, the coating solution may be effectively utilized without being wasted. More importantly, for existing solar panels, the portable coating device is capable of directly applying the coating solution onto the solar panel without being restricted by the field.

It will be apparent to those skilled in the art that various modifications and variations can be made to the structure of the disclosed embodiments without departing from the scope or spirit of the disclosure. In view of the foregoing, it is intended that the disclosure covers modifications and variations of this disclosure provided they fall within the scope of the following claims and their equivalents.

What is claimed is:

1. A portable coating device configured to apply a coating solution onto a solar panel, the portable coating device comprising:
a supply module;
a base;
a spraying module disposed on the base and connected to the supply module;
a transmission module disposed at two opposite ends of the base so that the base spans the solar panel, wherein the base moves on the solar panel through support of the transmission module;
an arc bracket disposed at a bottom of the base and having a plurality of seepage openings; and
an applicator comprising a porous material that deforms under pressure, wherein the applicator is assembled to the base and supported by the arc bracket,
wherein the supply module transmits the coating solution to the spraying module, and the spraying module sprays the coating solution onto the arc bracket so that the coating solution seeps to the applicator through the seepage openings to be adsorbed by the applicator, and as the base moves on the solar panel through the transmission module, the applicator abuts the solar panel to apply the coating solution onto the solar panel.

2. The portable coating device according to claim 1, wherein the spraying module comprises a plurality of nozzles arranged along an extension direction of the base, each of the nozzles is disposed through the base to face an inner surface of the arc bracket, the coating solution transmitted from the supply module is transmitted to the nozzles, and the nozzles spray the coating solution onto the arc bracket.

3. The portable coating device according to claim 1, wherein the transmission module comprises a pair of transmission components and at least one motor, the pair of transmission components are separately disposed at the two opposite ends of the base so that the spraying module is located between the pair of transmission components, each of the transmission components comprises a U-shaped bracket and at least one guide wheel, the U-shaped bracket is movably assembled to the base and spans the base, the at least one guide wheel is disposed at an end of the U-shaped bracket so that the U-shaped bracket is supported on the solar panel through the at least one guide wheel, and the motor is connected to and drives the at least one guide wheel.

4. The portable coating device according to claim 3, wherein the at least one guide wheel moves on a frame of the solar panel so that the applicator moves on protective glass inside the frame.

5. The portable coating device according to claim 3, further comprising at least one adjustment screw that movably locks the base and the U-shaped bracket to adjust a gap of the base and the applicator assembled thereon relative to the protective glass of the solar panel.

6. The portable coating device according to claim 5, further comprising a spring that is disposed through the U-shaped bracket and abuts between the base and the U-shaped bracket, wherein the spring constantly drives the U-shaped bracket away from the base.

7. The portable coating device according to claim 3, further comprising a front drive wheel that is connected between the U-shaped brackets of the pair of transmission components and maintains a distance from the applicator, wherein in response to the base moving on the solar panel and the applicator applying the coating solution onto the solar panel, the front drive wheel travels in front of the applicator.

8. The portable coating device according to claim 1, wherein the applicator comprises a sponge and a fabric, the sponge abuts an outer surface of the arc bracket, and the fabric tightly covers the sponge and is fixed to the base so that the sponge is located between the arc bracket and the fabric.

9. The portable coating device according to claim 8, wherein the applicator further comprises a reel and a clamping block, the clamping block is assembled to a first side of the base to clamp a side edge of the fabric, and the reel is disposed on a second side of the base to fix the other side edge of the fabric so that the fabric tightly abuts the sponge.

10. The portable coating device according to claim 9, wherein the applicator further comprises an adjustment block, a guide post, a spring, and an adjustment screw, wherein the guide post is disposed on the base and passes through the adjustment block, the adjustment block is movable along the guide post to move away from or close to the base, the spring is disposed through the adjustment block and one end of the spring abuts the base, the adjustment screw is movably locked to the adjustment block and abuts the other end of the spring, the adjustment screw is adapted to rotate under force to adjust a position of the adjustment block relative to the base, and the reel is assembled to the adjustment block.

11. The portable coating device according to claim 1, further comprising a support bar that is pivotally connected to the base to be held by a user.
